(19) United States
(12) Patent Application Publication
(10) Pub. No.: US 2025/0204015 A1
(43) Pub. Date: Jun. 19, 2025

(54) GATE STACK FOR FIELD EFFECT TRANSISTORS

(71) Applicant: Zinite Corporation, Edmonton (CA)

(72) Inventor: Kenneth C. Cadien, Edmonton (CA)

(21) Appl. No.: 18/539,556

(22) Filed: Dec. 14, 2023

(51) Int. Cl. H01L 29/51; H01L 29/786

(52) U.S. Cl. CPC H10D 64/685; H10D 30/6755

(57) ABSTRACT

A novel gate stack for a field effect transistor reduces the net charge in the dielectric material of the gate stack adjacent the semiconductor material of the transistor. The gate stack includes a gradient region between the dielectric layer abutting the semiconductor material and the diffusion barrier abutting the gate material, wherein the stoichiometry of the materials in the gradient region changes from the stoichiometry of the dielectric material to the stoichiometry of the diffusion barrier while avoiding abrupt changes in stoichiometry.

### FIELD OF THE INVENTION

The present invention relates to a gate stack for field effect transistors. More specifically, the present invention relates to a gate stack having a gate dielectric which transitions through a gradient to an adhesion layer, the gradient reducing stresses at the interface between the semiconductor channel of the transistor and the gate dielectric.

### BACKGROUND OF THE INVENTION

Field effect transistors (FETs), such as thin film transistors (TFTs) and other devices, are well known and are widely employed in VLSI chips, displays and other semiconductor devices. In order to increase circuit densities and reduce power requirements, much research and effort has been, and continues to be, devoted to decreasing the size of such transistors. However, as the size of semiconductor devices such as TFTs are reduced, manufacturing and performance issues can be exacerbated and/or new problems and faults can be introduced.

### SUMMARY OF THE INVENTION

It is an object of the present invention to provide a novel gate stack for semiconductor devices which obviates or mitigates a disadvantage of the prior art.

According to a first aspect of the present invention, there is provided a field effect transistor comprising: a source; a drain; a semiconductor extending between the source and the drain; a gate located over the semiconductor; and a gate stack formed between the semiconductor material and the gate, the gate stack including a dielectric layer abutting the semiconductor material, and a diffusion barrier layer abutting the gate, the gate stack including a gradient region between the dielectric layer and the diffusion barrier wherein the stoichiometry of the materials in the gradient region changes from the stoichiometry of the dielectric material to the stoichiometry of the diffusion barrier.

Preferably, the materials in the gradient region have stoichiometric ratios in the form of XOiNj where X is the base material, Oi is the oxygen content and Nj is the nitrogen content.

In another aspect of the present invention, there is provided a gate stack for use in a field effect transistor having a source, a drain a semiconductor connecting the source and the drain and having a gate located over the semiconductor, comprising: a dielectric material abutting the semiconductor; a diffusion barrier abutting the gate; and a gradient material between the dielectric material and the diffusion barrier, the gradient region comprising a graded transition between the dielectric material and the diffusion barrier to reduce stressed between the dielectric material and the diffusion barrier.

The present invention provides a gate stack for a field effect transistor to reduce net charge in the dielectric material of the gate stack adjacent the semiconductor material of the transistor. The gate stack includes a gradient region between the dielectric layer abutting the semiconductor material and the diffusion barrier abutting the gate material, wherein the stoichiometry of the materials in the gradient region changes from the stoichiometry of the dielectric material to the stoichiometry of the diffusion barrier while avoiding abrupt changes in stoichiometry.

### BRIEF DESCRIPTION OF THE DRAWINGS

Preferred embodiments of the present invention will now be described, by way of example only, with reference to the attached Figures, wherein:

FIG. 1 shows a schematic view of a prior art thin film transistor;

FIG. 2 shows a schematic representation of a thin film transistor in accordance with an aspect of the present invention; and

FIG. 3 shows an expanded view of a gate stack of the transistor of FIG. 2.

### DETAILED DESCRIPTION OF THE INVENTION

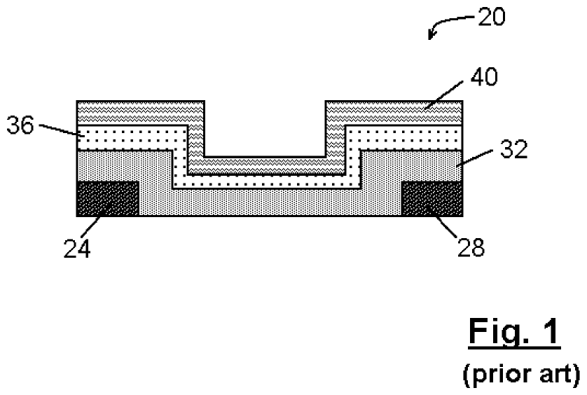

A prior art TFT is indicated generally at 20 in FIG. 1. TFT 20 includes a source 24 and a drain 28 which are formed on a suitable substrate (not shown). A semiconductor material 32, such as a metal oxide, is formed between source 24 and drain 28 and a gate dielectric material 36 is formed over semiconductor material 32. A gate 40, typically a metal, is then formed over gate dielectric material 36. As is well understood, when a voltage is applied to gate 40, a conductive channel can form through semiconductor material 32, between source 24 and drain 28, allowing current to flow therebetween.

As mentioned above, as semiconductor devices such as TFT 20 are fabricated in smaller sizes, a variety of challenges can arise. For example, dielectric material 36 can be subject to mechanical stresses due to the different thermal expansion rates of the dielectric, semiconductor and gate metal materials during the process of annealing of TFT 20 and these stresses can result in interstitial faults, vacancies and/or discontinuities in dielectric material 36 which can produce a net charge in dielectric material 36, in particular at the interface between dielectric material 36 and semiconductor material 32. The presence of such a net charge at the gate of TFT 20 is problematic as it reduces the performance of TFT 20.

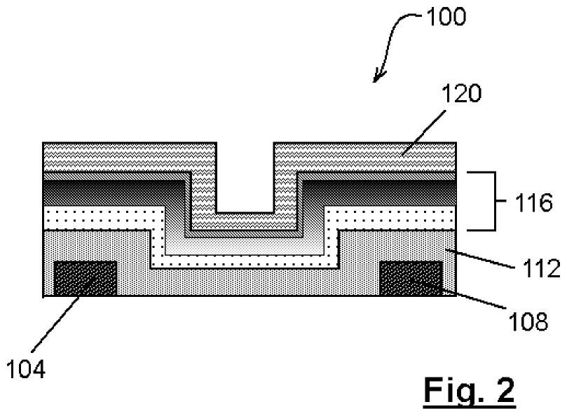

FIG. 2 shows a TFT100 in accordance with an aspect of the present invention. Similar to TFT 20 described above, TFT 100 includes a source 104 and a drain 108, each of which is formed on a suitable substrate (not shown), and a semiconductor material 112 that is formed between source 104 and drain 108.

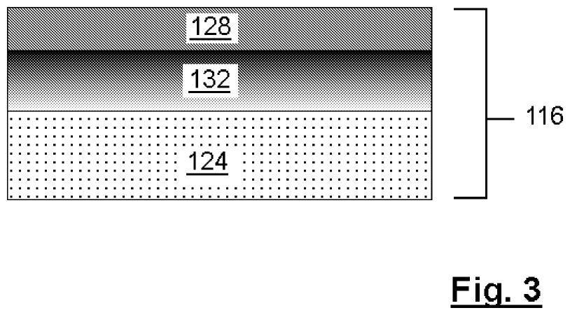

A gate dielectric stack 116 is then formed over semiconductor material 112 and a gate 120, typically a metal, is formed over gate stack 116. Stack 116 is shown in more detail in FIG. 3 and, as can be seen in the Figure, stack 116 includes a layer 124 of a dielectric material, such as an oxide, and a layer 128 of a suitable diffusion barrier material (to inhibit infusion of the gate metal into the stack 116), such as a nitride.

Stack 116 further includes a gradient region 132 located between dielectric layer 124 and diffusion barrier layer 128 and gradient region 132 provides a graded transition between the material of dielectric layer 124 and the material of diffusion barrier layer 128.

As an example, if stack 116 is being formed with an Atomic Layer Deposition (ALD) process, and dielectric layer 124 is an oxide such as hafnium oxide (HfO2) and diffusion barrier layer 128 is a nitride such as hafnium nitride (HfN), then gradient region 132 will be formed with multiple ALD cycles of different mixtures of Hf, O and N. Specifically, the deposited layers of gradient region 132 will have stoichiometric ratios of the form of HfOiNj, where i and j indicate the average ratio of each of oxygen and nitrogen in the deposited layer and in general, the stoichiometric ratios will be in the form of XOiNj where X is the base material such as Hafnium, Zirconium, etc.

For example, the portion of gradient region 132 formed in the first several cycles of ALD processing and abutting dielectric layer 124 can have a stoichiometry of HfO1.9N0.1 and the portion on top of it, formed by the next several cycles of ALD processing can have a stoichiometric ratio of HfO1.7N0.3 and so on until the portion of gradient region 132 formed by the final few cycles of ALD processing and abutting diffusion barrier layer 128 can have a stoichiometry of HfO0.1N0.9.

It should now be apparent to those of skill in the art that the specific stoichiometric ratios of each cycle(s) of gradient region 132 are not particularly limited and it is merely required that the formed layers provide a reasonable gradient from the composition of dielectric layer 124 to the composition of diffusion barrier layer 128. Preferably the gradient in gradient region 132 from the stoichiometry of dielectric layer 124 to the stoichiometry of diffusion barrier layer 128 is monotonic, but it will be apparent to those of skill in the art that ALD processes may not be able to achieve a totally monotonic gradient and minor variations in the stoichiometry of the deposited layers are easily tolerated while avoiding abrupt changes in stoichiometry.

It will also be apparent to those of skill in the art that FIG. 3 is not drawn to scale and gradient region 132 may be much thinner than illustrated, relative to dielectric layer 124 and/or diffusion barrier layer 128.

In one example of a compete gate stack 116, dielectric layer 124 can have a thickness of less than ten nanometers (nm), and preferably between from about seven point five nm to about five nm, diffusion barrier layer 128 can have a thickness of five nm or less and preferably from about three point five nm to two nm and gradient region 132 can have a thickness of from about one nm to about two nm.

In a presently preferred aspect of the present invention, semiconductor material 112 is tin oxide (SnO2), dielectric material layer 124 is hafnium oxide (HfO2) and diffusion barrier layer is hafnium nitride (HfN), with gradient region 132 have stoichiometry ratios of the form HfOiNj. However, the present invention is not so limited and different semiconductor materials such as indium gallium zinc oxide (IGZO), zinc oxide and others can be employed. Further, dielectric material 128 is not limited to hafnium oxide and instead can be a variety of materials, for example, zirconium oxide (ZrO2) and diffusion barrier material 128 can be zirconium nitride (ZrN) and gradient region 132 can have stoichiometry ratios of the form ZrOiNj.

As will be apparent to those of skill in the art, the present invention is not limited to use with a tin oxide semiconductor and a variety of other semiconductor materials, such as zinc oxide and indium gallium zinc oxide (IGZO), can be usefully employed.

The provision of gradient region 132 between dielectric layer 124 and diffusion barrier layer 128 reduces the mechanical stresses which may otherwise result from annealing processing of transistor 100 and other causes of net charge in dielectric layer 124.

Further, when diffusion barrier 128 is a nitride, it can also serve as an adhesion layer for the metal of gate 120.

As will now be apparent, the present invention provides a gate stack for a field effect transistor to reduce net charge in the dielectric material of the gate stack adjacent the semiconductor material of the transistor. The gate stack includes a gradient region between the dielectric layer abutting the semiconductor material and the diffusion barrier abutting the gate material, wherein the stoichiometry of the materials in the gradient region changes from the stoichiometry of the dielectric material to the stoichiometry of the diffusion barrier while avoiding abrupt changes in stoichiometry.

The above-described embodiments and aspects of the invention are intended to be examples of the present invention and alterations and modifications may be effected thereto, by those of skill in the art, without departing from the scope of the invention which is defined solely by the claims appended hereto.

We claim:

1. A field effect transistor comprising:
a source;
a drain;
a semiconductor extending between the source and the drain;
a gate located over the semiconductor; and
a gate stack formed between the semiconductor material and the gate, the gate stack including a dielectric layer abutting the semiconductor material, and a diffusion barrier layer abutting the gate, the gate stack including a gradient region between the dielectric layer and the diffusion barrier wherein the stoichiometry of the materials in the gradient region changes from the stoichiometry of the dielectric material to the stoichiometry of the diffusion barrier.

2. The transistor of claim 1 wherein the change in stoichiometry in the gradient region is substantially monotonic.

3. The transistor of claim 1 wherein the diffusion barrier also serves as an adhesion layer for the gate.

4. The transistor of claim 1 wherein the materials in the gradient region have stoichiometric ratios in the form of XOiNj where X is the base material, Oi is the oxygen content and Nj is the nitrogen content.

5. The transistor of claim 4 wherein the base material X is hafnium.

6. The transistor of claim 4 wherein the base material X is zirconium.

7. The transistor of claim 1 wherein the semiconductor is tin oxide.

8. The transistor of claim 1 wherein the semiconductor is IGZO.

9. A gate stack for use in a field effect transistor having a source, a drain a semiconductor connecting the source and the drain and having a gate located over the semiconductor, comprising:
a dielectric material abutting the semiconductor;
a diffusion barrier abutting the gate; and
a gradient material between the dielectric material and the diffusion barrier, the gradient region comprising a graded transition between the dielectric material and the diffusion barrier to reduce stressed between the dielectric material and the diffusion barrier.

10. The gate stack of claim 9 where the dielectric material has the form of XO, the diffusion barrier has the form XN and the gradient material has the form XOᵢNⱼ, where i decreases and j increases in the gradient region, from the region adjacent the dielectric material to the region adjacent the diffusion barrier.

11. The gate stack of claim 10 wherein X is hafnium.

12. The gate stack of claim 11 wherein the diffusion barrier also acts as an adhesion layer for the gate.
